(19) United States
(12) Patent Application Publication
(10) Pub. No.: US 2024/0286890 A1
(43) Pub. Date: Aug. 29, 2024

(54) DOUBLE LAYER MEMS DEVICES

(71) Applicant: Murata Manufacturing Co., Ltd., Nagaokakyo-shi (JP)

(72) Inventors: Altti TORKKELI, Tuusula (FI); Masakazu FUKUMITSU, Nagaokakyo-shi (JP); Anssi BLOMQVIST, Helsinki (FI); Matti LIUKKU, Helsinki (FI); Ville-Pekka RYTKÖNEN, Klaukkala (FI); Tadayuki OKAWA, Nagaokakyo-shi (JP); Petteri KILPINEN, Espoo (FI)

(21) Appl. No.: 18/585,802

(22) Filed: Feb. 23, 2024

(30) Foreign Application Priority Data
Feb. 27, 2023 (EP) 23158813.8

(51) Int. Cl. B81B 3/00; B81C 1/00

(52) U.S. Cl. CPC B81B 3/0072; B81B 3/0051; B81C 1/00666; B81C 1/00984; B81B 2201/0228

(57) ABSTRACT

A MEMS device is provided that includes a handle layer having a cavity and a suspension structure, a first device layer including a static electrode, a second device layer including a seismic element moveably suspended above the first device layer and a cap layer. The seismic element acts as the moveable electrode or the seismic element is mechanically coupled to move with the moveable electrode. The handle layer, the first device layer, the second device layer and the cap layer, a first electrically insulating layer between the handle layer and the first device layer, and a second electrically insulating layer between the first device layer and the second device layer form an enclosure that accommodates the seismic element, the static electrode and the moveable electrode.

### CROSS REFERENCE TO RELATED APPLICATIONS

The application claims priority to European Patent Application No. 23158813.8 filed Feb. 27, 2023, the entire contents of which are hereby incorporated by reference.

### TECHNICAL FIELD

The present invention relates to MEMS devices and a method of producing MEMS devices. More particularly, the present invention relates to MEMS devices comprising two device layers and to methods for manufacturing double layer MEMS devices.

### BACKGROUND

Microelectromechanical systems (MEMS) devices manufactured using silicon-based technology are widespread. A typical application of MEMS device is an inertial sensor that detects at least one of acceleration and angular velocity. MEMS devices of this type are widely used in consumer, automotive and industrial applications.

Capacitive sensing in MEMS devices is implemented by detecting change of capacitance caused by change in distance between two electrodes. Typically, capacitance is sensed between a moveable electrode and one or more static electrodes.

In typical capacitive MEMS devices for inertial sensing, static electrodes are provided on a substrate, such as a handle or a cap wafer. For example, a metal electrode may be provided on a surface of the substrate wafer. The MEMS device is subject to various sources of stress. During packaging of components, some steps of the process such as molding applies pressure on the substrate. Different materials have different thermal characteristics and therefore the substrate may also be subject to pressure due to differences in thermal expansion of materials within the MEMS device package. The MEMS device may also be subject to various external forces causing changes in the shape of the substrate. The environment in which the MEMS device is used may be subject to great temperature changes, vibration, impacts and so on, all causing stress on the MEMS device. When static electrodes are attached to the substrate, any change in form of the substrate caused by stress may also affect distance between the static electrodes and respective moveable electrodes. This causes risk of deterioration of accuracy of capacitive sensing.

In the following description, reference will be made to an inertial MEMS sensor and to the problems for the manufacturing thereof. However, the present disclosure generally applies to other types of MEMS devices. For example, the MEMS device may comprise one or more of the following structures, single or combined with each other: accelerometer, gyroscope, geophone, inclinometer and resonator. Furthermore, the MEMS device may be a MEMS actuator.

U.S. Patent Publication No. 2020/0156930 discloses a double side capacitive sensing MEMS device having a hollow body. This device is manufactured by epitaxial growing of a polysilicon (poly-Si) structure. Basic principle of manufacturing a silicon-on-insulator (SOI) structure is to use insulator, such as silicone dioxide, as a sacrificial layer in isotropic etching steps. A gap between two overlapping layers is implemented by isotropic etching holes provided in a polysilicon layer. However, perforation of the poly-Si mass reduces seismic mass and capacitance and thus reduces sensitivity of the sensor device.

Moreover, U.S. Patent Publication No. 2021/0363000 A1 discloses a MEMS device and a process for manufacturing a MEMS device that applies growth of a thick epitaxial polysilicon to determine two structural layers.

Furthermore, U.S. Patent Publication No. 2016/0090297A1 discloses a SOI MEMS devices with MEMS platform separated from the rest of a substrate layer by stress-relief gaps and a process for manufacturing such devices.

### SUMMARY OF THE INVENTION

In view of the foregoing, it is an object of the exemplary aspects of the present disclosure provide a method and apparatus to improve accuracy of a MEMS device in case of stress affecting the MEMS device.

In an exemplary aspect, a microelectromechanical system (MEMS) device is provided that includes at least one capacitive electrode pair comprising at least one static electrode and at least one moveable electrode; a handle layer comprising at least one cavity and at least one suspension structure; a first device layer comprising the at least one static electrode; a second device layer comprising at least one seismic element moveably suspended above the first device layer, the at least one seismic element being configured as the at least one moveable electrode or being mechanically coupled to move with the at least one moveable electrode; a cap layer; a first electrically insulating layer between the handle layer and the first device layer; and a second electrically insulating layer between the first device layer and the second device layer. In this aspect, the at least static electrode is suspended above the cavity by at least one of the at least one suspension structure disposed in the at least one cavity and at least one suspension structure disposed in the second device layer. Moreover, the handle layer, the first device layer, the second device layer, the cap layer, the first electrically insulating layer and the second electrically insulating layer are configured to form an enclosure that accommodates the at least one seismic element, the at least one static electrode and the at least one moveable electrode.

In another aspect, a method is provided for manufacturing a MEMS as described above. In this aspect, the method includes forming the handle layer out of a mono-Si handle wafer, the forming of the handle layer comprising forming at least one cavity and simultaneously forming the at least one suspension structure on a first face of the handle layer, and covering the first face of the handle layer with a first electrically insulating layer; forming the second electrically insulating layer on a first mono-Si wafer; fusion bonding a second mono-Si wafer on the second electrically insulating layer; forming the first device layer out of the second mono-Si wafer, the forming of the first device layer comprising thinning the second mono-Si wafer into a first thickness and forming a plurality of first trenches extending through the first device layer by dry etching, wherein the first device layer comprises the at least one static electrode; fusion bonding the first device layer on the first electrically insulating layer on the first face of the handle layer; forming the second device layer out of the second mono-Si wafer, the forming of the second device layer comprising thinning the first mono-Si wafer into a second thickness, forming at least one recessed area in the first mono-Si wafer and dry etching a plurality of second trenches extending through the first mono-Si wafer; releasing structural elements of the first and second device layer by removing exposed portions of the first and second electrically insulating layers over thickness of the first and second electrically insulating layers by etching; and enclosing the structural elements within the enclosure by bonding the cap layer on top of the second device layer.

The exemplary aspects of the present disclosure are based on the idea of having two suspended device layers in the MEMS device: a first device layer comprises suspended, non-moving structural elements and a second device layer comprises suspended seismic, moveable masses. Structural elements in the first device layer are suspended to a handle layer and/or via the second device layer to a cap layer by rigid suspension structures, such as anchors. The first device layer comprises structures used as static electrodes and the first device layer may also be used for electrical routing. The second device layer comprises seismic masses used as moveable electrodes and/or seismic masses coupled to moveable electrodes. As known in the art, suspension of seismic masses typically comprises flexible suspension structures such as springs and beams that are designed to enable one or more wanted movement directions of the seismic mass but to suppress any unwanted movement directions of the seismic mass. Both device layers are made of monocrystalline silicon (mono-Si), manufactured using a silicon-on-insulator, SOI, process that utilizes etching, preferably dry etching such as deep reactive-ion etching (DRIE) or like, for determining functional elements in the device layers.

The exemplary aspects provide the advantage that the two device-layer structure improves accuracy of the MEMS device by providing mechanically stable structures within the MEMS device that are robust against stress deformation, while the exemplary device structure described herein also facilitates high design flexibility and small die area. Because both moving and static electrodes can be implemented as mechanically separated from the substrate (i.e., the handle layer and the cap layer), stress affecting the substrate does not cause changes in geometry of the structural elements in the device layers. Sensitivity to stress can further be improved by suspending both device layers on laterally common anchor locations. Some embodiments of the double silicon device layered design can be designed and manufactured without need for perforation of functional elements in the device layers, thus avoiding reduction of capacitance and mass caused by such perforation, which facilitates higher capacitance and improved sensitivity of the MEMS device.

### BRIEF DESCRIPTION OF THE DRAWINGS

In the following the invention will be described in greater detail, in connection with preferred embodiments, with reference to the attached drawings, in which:

FIG. 1 illustrates a cross-section of a MEMS device according to a first exemplary embodiment.

FIG. 2 illustrates a cross-section of a MEMS device according to a second exemplary embodiment.

FIG. 3 illustrates a signal path in a MEMS device.

FIGS. 4a to 4l illustrate a manufacturing process of a MEMS device according to a third exemplary embodiment.

FIGS. 5a to 5j illustrate a manufacturing process of a MEMS device according to the second exemplary embodiment.

FIG. 6 illustrates mains steps of a manufacturing process.

FIG. 7 illustrates a cross-section of a MEMS device with bumps on the cap layer.

FIG. 8 illustrates a cross-section of a MEMS device with poly-Si bumps in the first device layer.

FIGS. 9a to 9f illustrate a process for manufacturing poly-Si feedthroughs and bumps.

FIG. 10 illustrates a cross-section of a variation of the MEMS device according to the first embodiment.

FIG. 11 illustrates a cross-section of a variation of the MEMS device according to the third embodiment.

FIG. 12 illustrates a further variation of a MEMS device according to some embodiments.

Cross-section figures are not in scale.

### DETAILED DESCRIPTION

Single-crystal silicon, mono-Si, known also as monocrystalline silicon is the well-known base semiconductor material for silicon-based discrete components and integrated circuits. Monocrystalline silicon includes silicon in which the crystal lattice of the entire solid is continuous. Mono-Si is the material of first choice for robust MEMS devices, because of its excellent mechanical strength and elasticity, and the large variety of available standard processes. It is well known in the art, that in MEMS devices, mono-Si layer is used as a conductor, for which purpose it is doped to make it electrically conducting. For example, Boron-doped P-type silicon wafers are common, but also Phosphorus (P) doped N-type wafers are used in some special applications.

In this context, polysilicon, poly-Si, known also as polycrystalline silicon or multi-crystalline silicon refers to silicon consisting of small crystals, known as crystallites. Like mono-Si, also polysilicon is doped to make it electrically conducting.

In this context, silicone dioxide, known also as silica, is an oxide of silicon with chemical formula SiO₂. Silicon dioxide is an electrical insulator.

In the following description, direction up refers to direction of the positive z-axis and direction down is direction of negative z-axis for convenience. It is to be understood, that these directions are not to be understood as limiting the position of use of the MEMS device. The simplified MEMS device has only a limited number of structural elements, such as anchors, beams, electrical contacts, masses and/or limiters, often just one of each. It is understood by a skilled person that an actual MEMS device may comprise more than one of any of such structural elements.

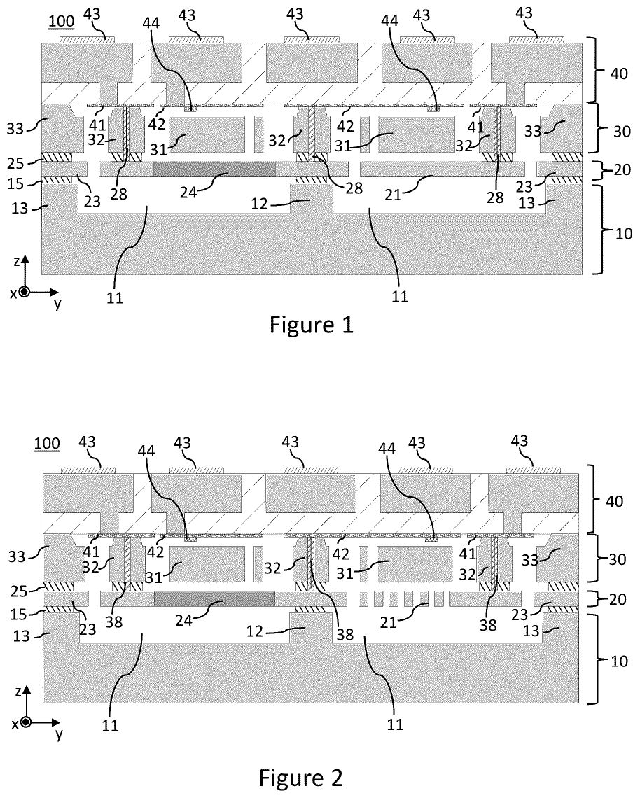

FIG. 1 illustrates a cross-section of a MEMS device according to a first exemplary embodiment.

Starting from the bottom of the MEMS device 100, first layer is a handle layer 10 made of mono-Si. The handle layer 10 comprises at least one cavity 11. In the cavity 11, there is at least one suspension structure 12 also known as anchor. The at least one cavity 11 is preferably formed as a basin such that it does not reach lateral sides of the bottom layer 10, so that walls 13 are provided in the handle layer 10 on the outer circumference thereof. The at least one cavity 11 increases distance from the bottom of the cavity 11 towards a first device layer 20 above the handle layer 10. The increased distance decreases unwanted parasitic capacitance between the handle layer 10 and structural elements in the superimposed first device layer 20.

Between the handle layer 10 and the first device layer 20, there is an electrically insulating layer 15. Most of the sacrificial electrically insulating layer 15 is removed in the manufacturing process, but as can be seen in the FIG. 1, portions of the electrically insulating layer 15 remain between the handle layer 10 and the first device layer 20. The electrically insulating layer is preferably made of silicon dioxide. The electrically insulating layer 15 facilitates bonding between the handle layer 10 and the first device layer 20, forms a part of walls of an enclosure in which all functional elements of the MEMS device are enclosed and is also used as sacrificial layer during manufacture, while supporting and protecting structures during manufacturing process before it is removed.

According to the exemplary aspect, the first device layer 20 made of mono-Si comprises structural elements that are mechanically suspended on the suspension structures 12 provided in the handle layer 10 and/or by suspension structures 32 provided in a second device layer 30 conveying suspension on the cap layer 40. Structural elements on the first device layer 20 are fixed. Mass of a static electrode can be smaller than what would be needed for a seismic mass. Therefore, thickness of the first device layer 20 may be relatively small, although thick enough to form essentially rigid structural elements that are not acting as springs. Structural elements on the first device layer 10 are advantageously used for example as static electrodes 21 in capacitive electrode pairs that may be used either for sensing or for driving purposes. Another possible use of structural elements on the first device layer 10 is for signal routing. This is illustrated by signal bearing beam 24 that may travel between a seismic element 31 on the second device layer 30 and the cavity 11. For reducing unwanted capacitance between the seismic element 31 and the signal bearing beam 24, the signal bearing beam 24 is preferably made narrow in lateral (x-axis) dimension so that overlapping area between the two is small.

The first device layer 20 preferably comprises a frame portion 23 that encircles structural elements of the first device layer 10 and forms part of outer walls of the enclosure that comprises structural elements of the MEMS device.

Because structural elements on the first device layer 20 are only supported to the handle layer 10 and/or via the second device layer 30 to the cap layer 40 by distinct suspension structures 12, 32, structural elements on the first device layer 20 are less sensitive to stress affecting the MEMS device 100: deformation of the cap layer 40 or the handle layer 10 due to stress causes less deformation or displacement of structural elements on the first device layer 20 and thus less change in distance occurs between structural elements of the first device layer to structural elements of the second device layer 30 due to mechanical stress affecting the MEMS device 100.

Above the first device layer 20, there is a second device layer 30 that comprises seismic elements 31 of the MEMS device 100. For facilitating seismic movement, seismic elements 31 can be increased by making the second device layer 30 thicker than the first device layer 20. Preferably, thickness of the second device layer 30 is at least twice the thickness of the first device layer 20.

Between the first device layer 20 and the second device layer 30, there is an electrically insulating layer 25. Majority of the sacrificial electrically insulating layer 25 is removed in the manufacturing process, but as can be seen in the FIG. 1, portions of the electrically insulating layer 25 remain between the first device layer 20 and the second device layer 30. The electrically insulating layer is preferably made of silicon dioxide. The electrically insulating layer 25 facilitates bonding between the first device layer 20 and the second device layer 30, forms a part of walls of an enclosure in which all functional elements of the MEMS device are enclosed and is also used as sacrificial layer during manufacture, while supporting and protecting structures during manufacturing process before removed.

Polysilicon feedthroughs 28 provide electrical connections over the electrically insulating layer 25 between the first device layer 20 and the second device layer 30, enabling carrying electrical signals to and from the first device layer 10.

The second device layer 30 is made of mono-Si and comprises seismic elements that are indirectly, via the first device layer 20, suspended on the suspension structures 12 provided in the handle layer 10 and/or by rigid suspension structures 32 within the second device layer 30 that are suspended on the cap layer 40. As known in the art, for enabling movement of the seismic elements 31, suspension thereof is implemented with springs and/or flexible beams (not shown).

The second device layer 30 preferably comprises a frame portion 33 that encircles structural elements of the second device layer 30 and forms part of outer walls of the enclosure that comprises structural elements of the MEMS device 100.

Structural parts of the first and second device layers 20, 30 are enclosed in an enclosure between the handle wafer 10 and a cap layer 40 that is bonded on top of the second device layer 30. Walls 13 of the handle wafer 10, frame portions 23, 33 of the first and second device layers 20, 30 together with insulator layers 15, 25 form walls of the enclosure.

In the shown example, the cap layer 40 comprises metallized contacts 41 on the bottom face of the cap layer 40 that both mechanically and electrically couple the support structures 32. Optionally, metallized patterns may also be provided on the bottom face of the cap layer 40 to operate as static electrodes 42. Metallized contacts 41 and static electrodes 42 are electrically coupled through the cap layer 40 to metallized contact pads 43 on the top side of the cap layer 40. When no electrical contact is required, support structures may be mechanically bonded to the cap layer 40 by anodic bonding. For maximum stress robustness, only the first device layer 10 should be used for static electrodes 21. Implementing further static electrodes 42 on the cap layer 40 makes the MEMS device more susceptible to the stress.

According to an exemplary aspect, the cap layer 40 may be provided with one or more bumps 44 that prevent the one or more seismic masses 31 from becoming into direct contact with the static electrodes 42 or other metallized patterns on the bottom face of the cap layer 40. Bumps 44 are preferably made of electrically insulating material such as SiO₂or Si₄N₄.

FIG. 2 illustrates a cross-section of a MEMS device according to a second exemplary embodiment. Majority of the features are similar to that of the first embodiment and are therefore not repeated.

In this embodiment, polysilicon feedthroughs 38 that electrically combine the first and the second device layers 20, 30, are manufactured in a different phase of the manufacturing process, namely during manufacturing of the second device layer 30, and extend therefore through the second device layer 30 and the electrically insulating layer 25.

It is noted that other structural difference from the first embodiment is that the static electrode 21 in the first device layer 20 is perforated to enable removal of the sacrificing electrically insulating layer 25 between the seismic mass 31 and the structural element 21. Perforation reduces capacitance between the static electrode 21 and the seismic mass 31, because the superimposed area between these two is reduced. However, also this embodiment has improved robustness against stress, because the static electrode 21 is not integrated to the cap layer 40 or the handle layer 10.

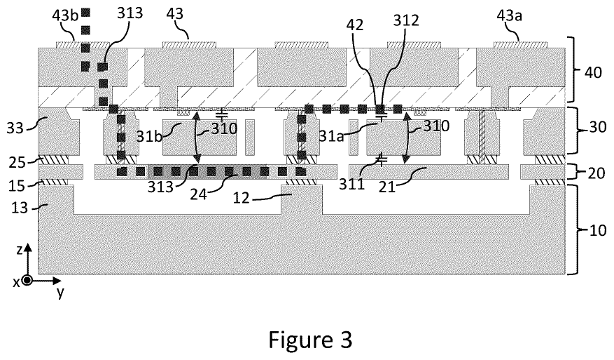

FIG. 3 is a simplified illustration that schematically features of the MEMS device that enable main technical benefits achieved. Structural parts of the MEMS device in this illustration corresponds to those of FIGS. 1 and 2, and some reference numbers have been omitted for clarity.

In this example, both seismic masses 31a, 31b are configured to move in vertical dimension, as illustrated by the curved arrows 310. Variable capacitances between the seismic mass 31a on the right and two static electrodes 21, 42 can be sensed as illustrated with capacitors 311 and 312 while distance between the seismic mass 31a changes. Electrical signal from the static electrode 21 is provided towards the contact pad 43a. The double-layer structure is utilized for routing electrical signal from the static electrode 42 all the way via two poly-Si feedthroughs 38 formed in the support structures 32 and via the signal bearing beam 24 to the contact pad 43b. This signal path is illustrated with the thick dotted line 313. Because in this example, the signal bearing beam 24 travels under the second seismic mass 31b, this second seismic mass 31b is not provided with a static electrode in the first device layer 20. Instead of implementing a signal path from the static electrode 42 on the cap layer 40, a like signal path may be provided for the static electrode 21 on the first device layer 20. As explained above, using a static electrode 42 on the cap wafer makes the device more sensitive to errors caused by stress. For maximizing robustness against stress, sole use of the first device layer for implementing static electrodes such as static electrode 21 is preferred.

It should be understood that this exemplary signal path is by no means limiting the scope but is intended to illustrate the enhancement in signal routing flexibility provided by use of two device layers that greatly facilitates improved freedom of design of device layers of the MEMS device.

FIGS. 1, 2 and 3 illustrate seismic masses 31, 31a, 31b that is as such used as the moveable electrode. Such arrangement is of course optional, and the moveable electrode may also be attached to a seismic mass such that movement of the seismic mass is conveyed to a movement of the moveable electrode.

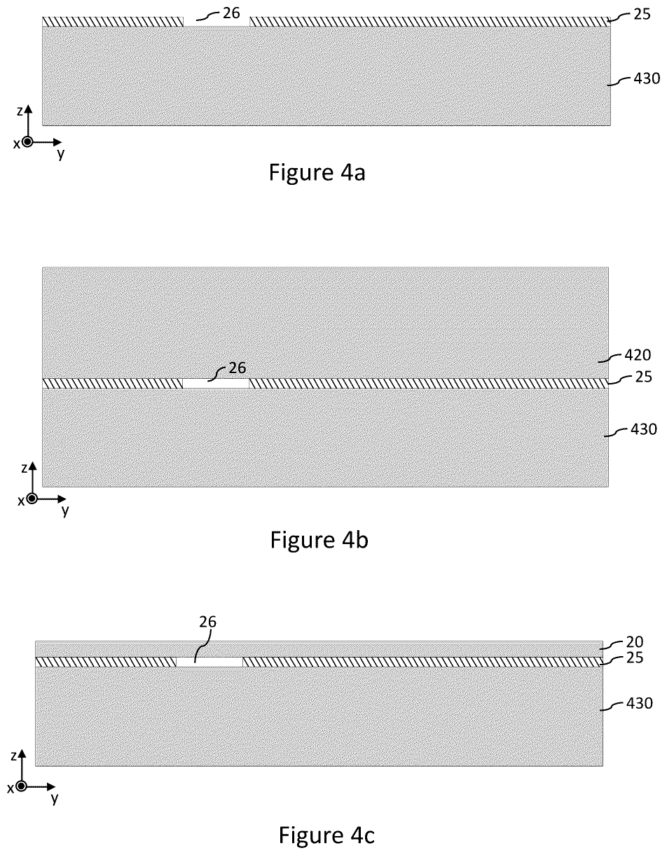

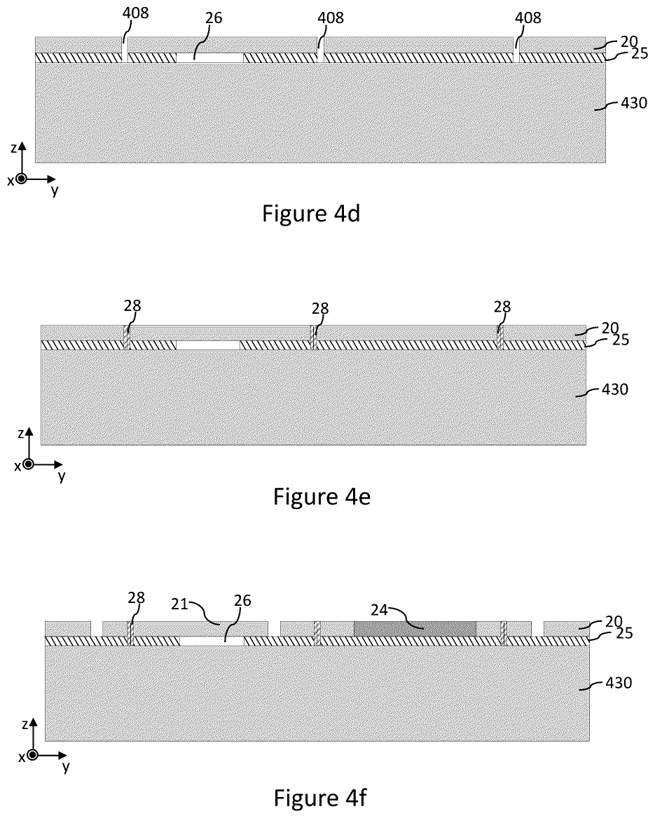

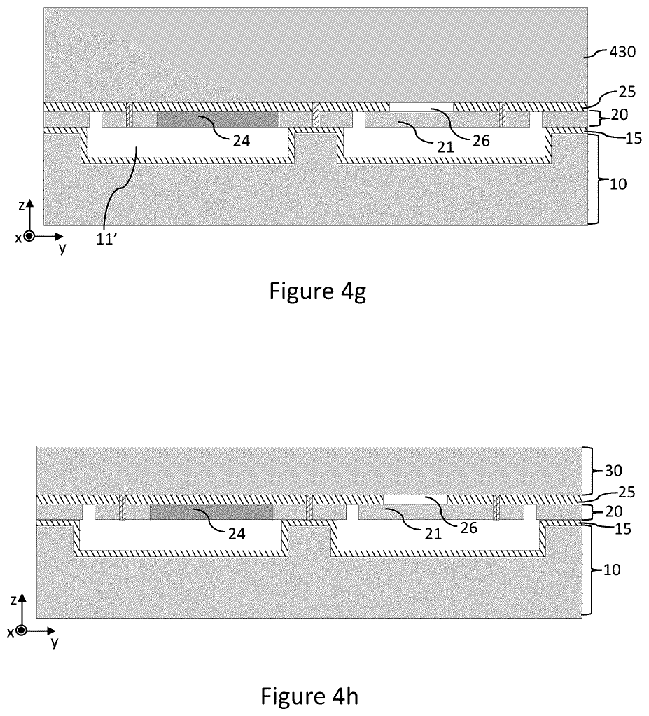

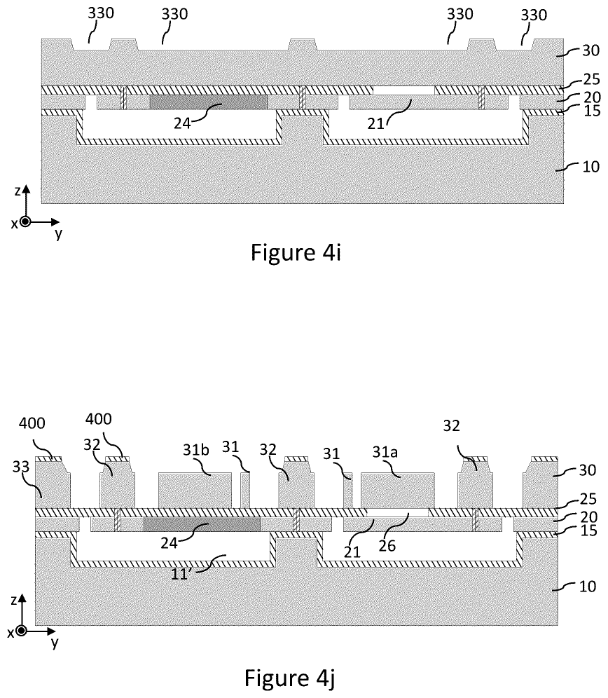

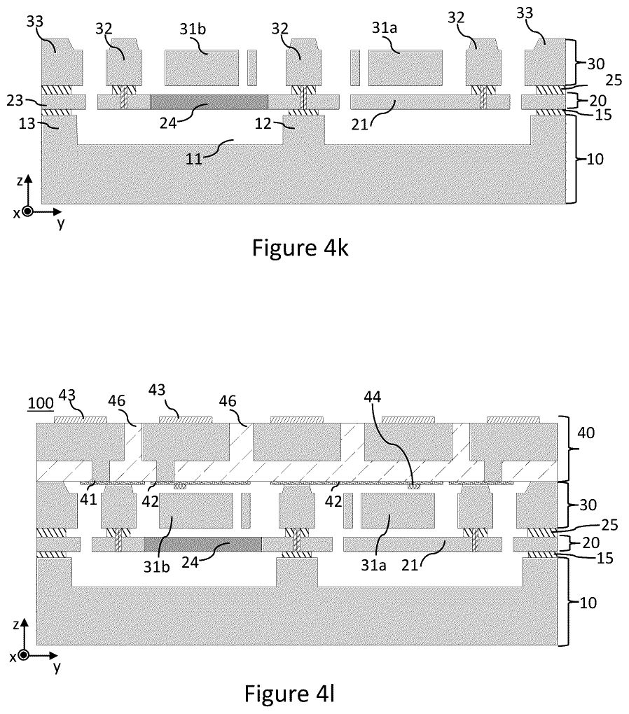

FIGS. 4a to 4l illustrate a manufacturing process of a MEMS device according to a third exemplary embodiment. In the third embodiment, poly-Si feedthroughs 28 that electrically and mechanically connect the first device layer 20 and the second device layer 30, travel through the first device layer 20.

FIG. 4a shows a second device wafer 430, which will be eventually become the second device layer. The second device wafer 430 is a mono-Si wafer. An electrically insulating layer 25, preferably of silicon dioxide is built on one face of the second device wafer 430. This electrically insulating layer 25 is generated using thermal oxidation. Depending on the MEMS device design, this electrically insulating layer 25 may be patterned by etching. Examples of applicable etching methods are wet etching by buffered hydrofluoric acid (BHF) and reactive ion plasma etching. This optional etching step may be referred to as pre-etching. In this example, pre-etching is used for removing a portion 26 of the electrically insulating layer 25 that would eventually reside between a capacitive electrode pair. Without removing the electrically insulating layer by pre-etching, perforation of a structural layer would be needed for removal of this unwanted portion of the electrically insulating layer 25 at the end of the process. Thus, the pre-etching step helps in increasing capacitance and mass and thus improving sensitivity of capacitive electrode pair.

FIG. 4b illustrates the next step, in which a first device wafer 420 is fusion bonded on top of the electrically insulating layer 25. The first device wafer 420 is also a mono-Si wafer.

Since the first device wafer 420 and the second device wafer 430 are both made of mono-Si, actual order of placing these can be freely selected. In this illustration, we have selected the naming based on order of processing the device layers and also reflecting the order of layers starting from the bottom of the finalized MEMS device structure.

FIG. 4c illustrates a step in which the first device wafer 420 is thinned. Thinning may be performed for example by grinding, plasma etching or wet chemical etching. Chemical mechanical polishing (CMP) is needed to provide smooth surface and to remove roughness after thinning and residual surface damages from grinding. Although the first device layer 20 still needs several manufacturing steps before it is ready, from this step onwards, the first device wafer 420 is referred to as the first device layer 20.

FIG. 4d illustrates a step that starts generation of poly-Si feedthroughs 28. Feedthrough holes 408 are generated in the first device layer 20 and further, the electrically insulating layer 25 at the bottom of these feedthrough holes 408 to reveal the second device wafer 430 at the bottom of these feedthrough holes 408. Preferably, DRIE etching is used for etching the first device layer 20 made of mono-Si, and buried oxide etching is used for removing portions of the electrically insulating layer 25. As known by a skilled person, buried oxide refers to the insulating oxide layer in the SOI wafer. Suitable etching methods for etching the buried oxide are for example wet etching by BHF and reactive ion plasma etching.

FIG. 4e illustrates result of poly-Si deposition. Poly-Si is deposited over the entire upper face of the first device layer 20 until the feedthrough holes 408 are filled with Poly-Si. Then any excess poly-Si is removed from the upper face for example by using grinding and chemical mechanical policing (CMP) so that only the defined poly-Si feedthroughs 28 remain. Also, plasma etching or wet chemical etching can be used. Polysilicon deposition is preferentially made using low-pressure chemical vapor process which deposits polysilicon layer also on the wafer backside, unless backside is masked during the deposition process, for example, with a blank wafer. Polysilicon layer in the wafer back side is not shown as it can be left there or removed using commonly known etching methods.

FIG. 4f illustrates patterning of the first device layer 20. The first device layer is preferably patterned using lithography and etching, such as DRIE etching. During patterning, fixed structures such as static electrodes 21 and signal bearing beam 24 are formed in the first device layer 20.

FIG. 4g illustrates a step after fusion bonding the first device layer 20 with the handle layer 10 that comprises at least one oxidized cavity 11′. For this purpose, the work item has been flipped upside down so that the first device layer 20 is downwards and the second device wafer 430 is on the top.

In the FIG. 4h, the second device wafer 430 has been thinned at least approximately into a thickness of the second device layer 30 for example by using grinding or etching. Chemical mechanical polishing (CMP) is used to provide smooth surface and to remove roughness after thinning and residual surface damages from grinding. Because the second device layer 30 comprises seismic masses, which beneficially have a large mass, thickness of the second device layer 30 is preferably at least two times the thickness of the first device layer 20.

FIG. 4i illustrates recessed portions 330 on the upper face of the second device layer 30. Recessing of the recessed portions 330 can be performed using a LOCal Oxidation of Silicon (LOCOS) process, where SiO₂ is formed in selected areas on the upper face of the second device layer 30 and subsequently the formed SiO₂ is removed by etching to form the recessed portions 330 on the surface. Other alternatives exist, such as etching. One purpose of this recession is to form free space above seismic masses such that they have room for movement in z-axis direction also after a cap layer has been placed on top. Alternative to LOCOS process, recess can be made using silicon wet etching or plasma etching.

FIG. 4j illustrates forming of support structures 32 and seismic masses 31a, 31b in the second device layer 30 by patterning and etching the mono-Si layer of using dry etching such as DRIE. Although not shown, support structures in the second device layer also comprise springs and/or beams that control movement of the seismic masses. During DRIE etching, the portions of the second device layer 30 such as the support structures 32, the poly-Si feedthroughs 38 and the frame portion 33 that are not to be etched are protected by a masking pattern 400 of, for example, Silicon dioxide (SiO₂).

FIG. 4k illustrates results of releasing structural elements in the first 20 and second device layers 30 by removing buried SiO₂. This can be performed using hydrofluoric acid (HF) vapor etching. In controlled HF release, a defined amount of SiO₂ is removed in all directions.

The HF release also removes electrically insulating layer from the cavity 11 and a portion of the electrically insulating layer between the handle layer 10 and the first device layer 20 on the suspension structures 12 and on the side walls 13, between supporting structures 32 and structural elements on the first device layer 20 and between frame portions 23, 33 of the first device layer 20 and the second device layer 10. A sufficient area of electrically insulating layer 15, 25 remains to maintain contact between the handle layer 10, the first device layer 20 and the second device layer 30 where needed. Pre-etching performed between the seismic mass 31a on the right-hand side and the underlying static electrode 21, which have a large lateral area between them for providing a high capacitance, avoids need to perforate the silicon layer in order to remove the electrically insulating layer between these by the HF release process step. On the other hand, pre-etching is not needed below the seismic mass 31b on the left-hand side, because the signal bearing beam 24 is thin enough in the x-axis direction such that the HF release can therefore remove all electrically insulating layer between the signal bearing beam 24 and the seismic mass 31b.

FIG. 4l illustrates the MEMS device 100 after functional elements have been enclosed in an enclosure by fixing a cap layer 40 on top of the second device layer 30. In this example, the cap layer 40 comprises glass 46 insulated silicon and metallized contacts 41, 43, possible static electrodes 42, and the cap layer 40 is attached using anodic bonding and using anodic bonding and subsequent back-end process. Instead of the glass insulated silicon cap layer, any other suitable type of cap layer can be used in any of the disclosed exemplary embodiments. For example, the cap layer may be an Integrated Circuit (IC) wafer with electrodes.

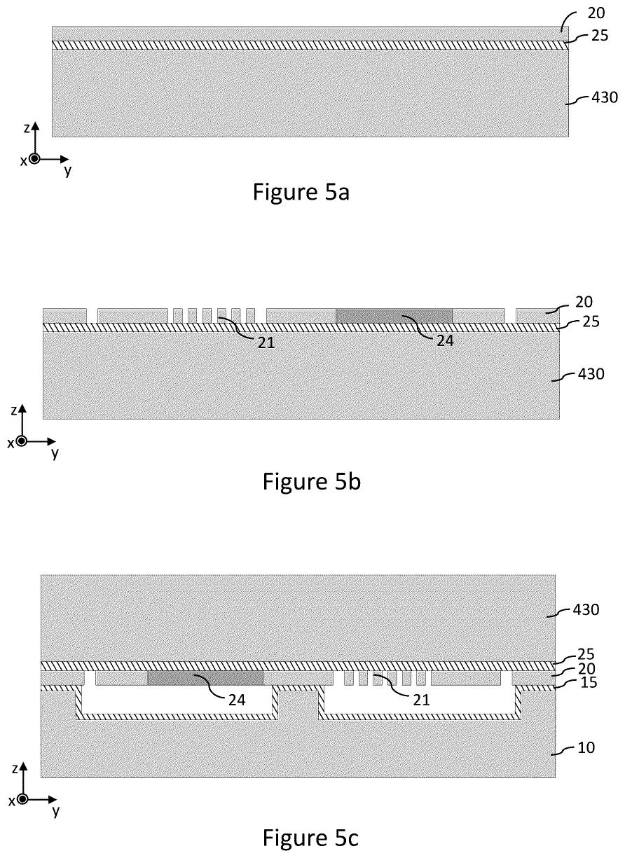

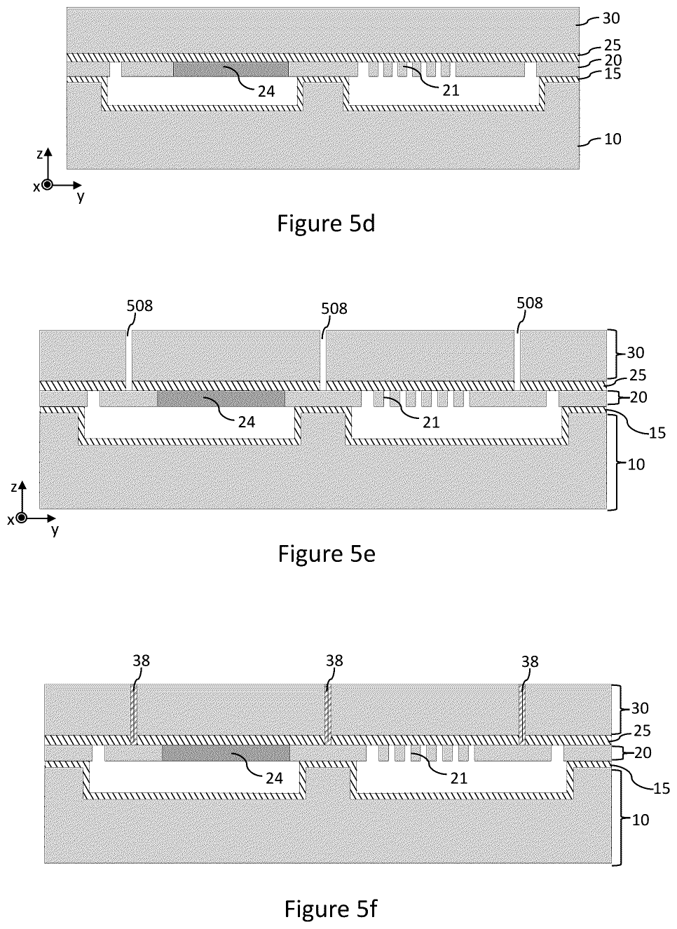

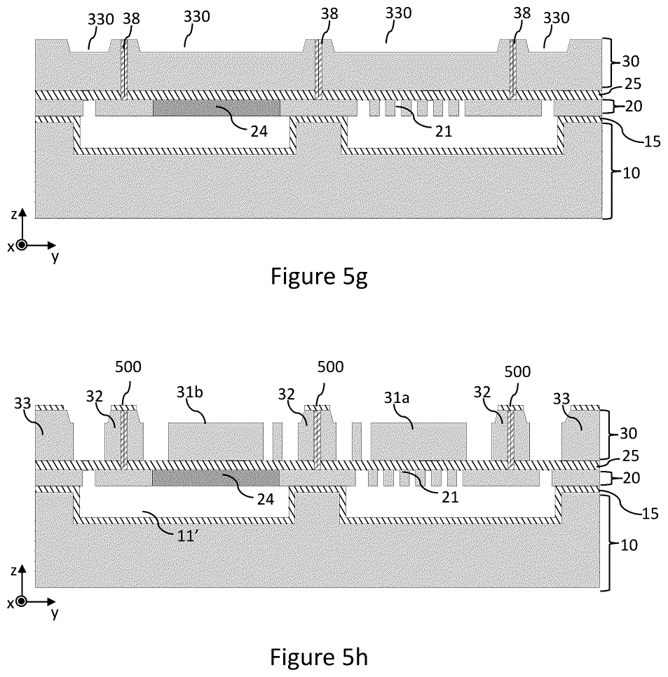

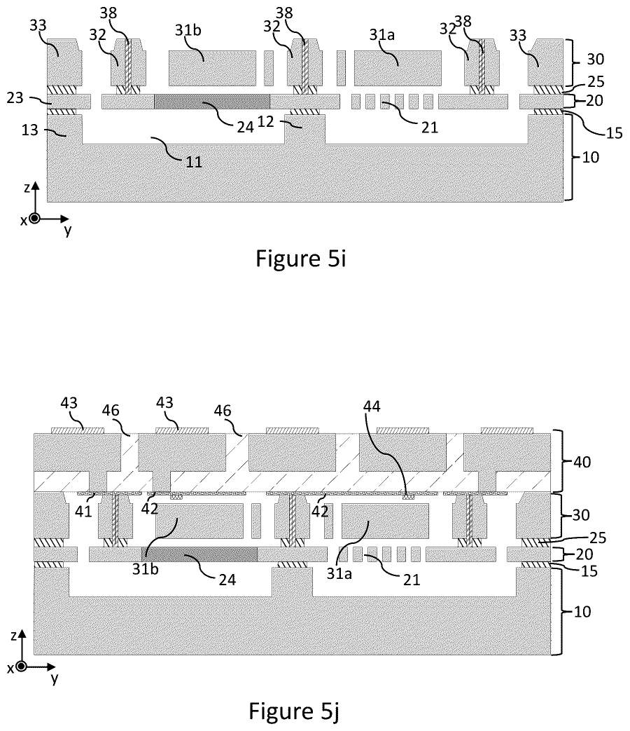

FIGS. 5a to 5j illustrate a manufacturing process of a MEMS device according to the second exemplary embodiment.

FIG. 5a illustrates a silicon on insulator (SOI) wafer comprising a second device wafer 430, an electrically insulating layer 25 and the first device layer 20. The first device layer 20 may be initially grinded and/or polished from a thicker first device wafer as seen in the FIGS. 4b and 4c, but in this manufacturing process variation, no pre-etching is performed, but the electrically insulating layer 25 fills the entire space between the two mono-Si layers.

FIG. 5b illustrates forming structures of the first device layer by dry etching, such as DRIE. The static electrode 21 is perforated. The signal carrying beam 24 is made thin in the x-axis direction as above.

In the FIG. 5c, the first device layer 20 is turned downwards by flipping the device upside down and fusion bonded to the oxidized handle wafer 10.

In the FIG. 5d, the second device wafer 430 has been thinned to form the second device layer 30. Thinning can be implemented for example by grinding and CMP.

In this alternative, electrical connection between the first device layer 20 and the second device layer 30 is created by manufacturing poly-Si feedthroughs through the second device layer 30. Other aspects of the process for manufacturing the poly-Si feedthroughs are similar as described above.

FIGS. 5e and 5f illustrate generation of Poly-Si feedthroughs in this exemplary embodiment.

FIG. 5e shows feedthrough holes 508 generated in the second device layer 30 and further, in the electrically insulating layer 25 at the bottom of these feedthrough holes 508 to reveal the first device layer 30 at the bottom of these feedthrough holes 508. Preferably, a combination of silicon DRIE etching, and silicon dioxide plasma etching is used for etching the second device layer 30 made of mono-Si, and buried oxide 25 under the feedthrough holes 508.

FIG. 5f illustrates the result of poly-Si deposition. Poly-Si is deposited over the entire upper face of the second device layer 30 until the feedthrough holes 508 are filled with Poly-Si. Then any excess poly-Si is removed from the upper face for example by using grinding and chemical mechanical policing (CMP) so that only the defined poly-Si feedthroughs 38 remain.

FIG. 5g illustrates recessed portions 330 on the upper face of the second device layer 30. Recessing of the recessed portions 330 can be performed for example using a LOCal Oxidation of Silicon (LOCOS) process, where SiO₂ is formed in selected areas on the upper face of the second device layer 30 and subsequently the formed SiO₂ is removed by etching to form the recessed portions 330 on the surface. One purpose of this recession is to form free space above seismic masses such that they have room for movement in z-axis direction also after a cap layer has been placed on top.

FIG. 5h illustrates forming of support structures 32 and seismic masses 31a, 31b in the second device layer 30 by etching the mono-Si layer using dry etching such as DRIE. Although not shown, support structures in the second device layer also comprise springs and/or beams that control movement of the seismic masses. During DRIE etching, the portions of the second device layer such as the support structures 32, the poly-Si feedthroughs 38 and the frame portion 33 that are not to be etched are protected by a protecting mask pattern 500 like SiO₂.

FIG. 5i illustrates results of releasing structural elements in the first 20 and second device layers 30 by removing SiO₂. This can be performed using hydrofluoric acid (HF) vapor etching. In controlled HF release, a defined amount of SiO₂ is removed in all directions. The HF release also removes electrically insulating layer from the cavity 11 and a portion of the electrically insulating layer between the handle layer 10 and the first device layer 20 on the suspension structures 12 and on the side walls 13, between supporting structures 32 and structural elements on the first device layer 20 and between frame portions 23, 33 of the first device layer 20 and the second device layer 10. Sufficient electrically insulating layer 15, 25 remains to maintain contact between the handle layer 10, the first device layer 20 and the second device layer 30 where needed. Perforation of the static electrode 21 enables removing all electrically insulating layer material between the seismic mass 31a and the static electrode 21.

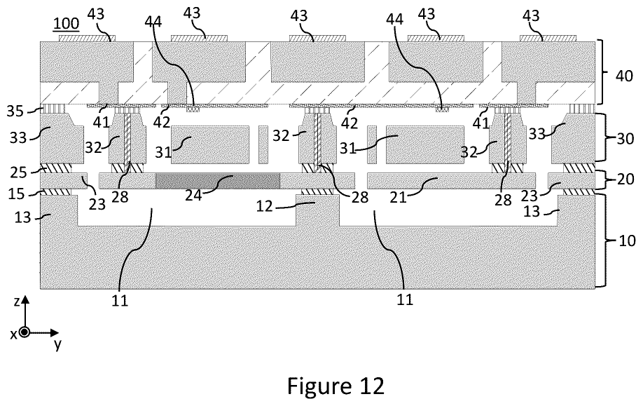

FIG. 5j illustrates the MEMS device 100 after functional elements have been enclosed in an enclosure by fixing a cap layer 40 on top of the second device layer 30. In this example, the cap layer 40 comprises glass 46 insulated silicon and metallized contacts 41, 43, possible static electrodes 42, and the cap layer 40 is attached using anodic bonding and subsequent back-end process. Instead of the glass insulated silicon cap layer, any other suitable type of cap layer can be used. Also, other wafer bonding than anodic bonding can be used. For example, eutectic bonding using aluminum and germanium can be used. The aluminum and germanium layers are deposited and patterned to cap and structure wafers before bonding. A MEMS device with eutectic bonding is illustrated in the FIG. 12.

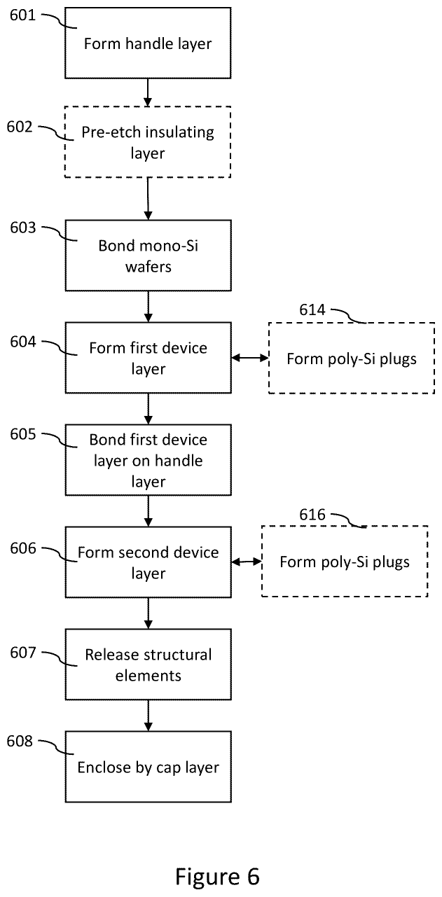

The MEMS device 100 according to the first embodiment can be manufactured by a suitable combination of the manufacturing processes shown in FIGS. 4a to 4i and FIGS. 5a to 5j. While mainly following the process as shown in FIGS. 5a to 5j, the pre-etching step shown in the FIG. 4a is preferably applied for removing a portion 26 of the electrically insulating layer 25 that will eventually reside between a capacitive electrode pair, thus avoiding the need for perforating large structural elements in the first device layer 20. FIG. 6 illustrates main steps of a manufacturing process according to exemplary embodiments.

In the step 601, the handle layer 10 is formed out of a mono-Si wafer. Preferably, the handle layer 10 comprises at least one cavity 11′ and the upper face of the handle layer 10 is protected by an electrically insulating layer 15. The at least one cavity 11′ comprises one or more suspension structures 12 such as anchors. The at least one cavity is basin-like, which means that there are side walls 13 about the at least one cavity 11′.

In optional step 602, an electrically insulating layer 25 laid on a first device wafer 420 is pre-etched.

In the step 603 the first device wafer 420 and the second device wafer 430 are fusion bonded to each other, connected by the electrically insulating layer 25. The first device wafer 420 and the second device wafer 430 are both mono-Si wafers.

In the step 604 structural elements of the first device layer 20 are formed. This forming process includes thinning the first device wafer 420 to a defined thickness of the first device layer 20 and dry etching the mono-Si material of the first device layer 20. Optionally, steps of forming the first device layer 20 comprise forming poly-Si feedthroughs for electrically connecting the first device layer 20 and the second device wafer 430 as illustrated with step 614.

In the step 605, the first device layer is fusion bonded on the handle layer 10.

In the step 606, structural elements of the second device layer 30 are formed. This forming process includes thinning the second device wafer 430 to a defined thickness of the second device layer 30 and dry etching the mono-Si material of the second device layer 30. As an alternative to step 614, steps of forming the second device layer 30 comprise forming poly-Si feedthroughs for electrically connecting the first device layer 20 and the second device wafer 430 as illustrated with step 616.

In the step 607, structural elements of the first device layer 20 and the second device layer 30 are released. Releasing can be performed by HF vapor etching, which also removes insulating material from the cavities 11 in the handle layer. Depending on design and dimensions of the structural elements in the first device layer 20 and the second device layer 30, amount of removal of insulating material varies.

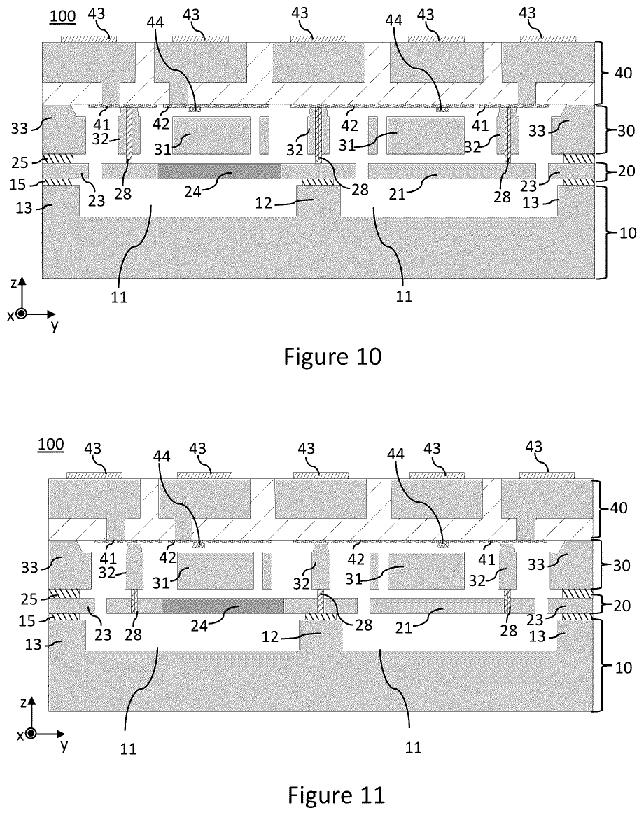

For releasing laterally large areas, the pre-etching step 602 may be utilized. As explained above, perforation of a laterally large structural element facilitates effective removal of insulating material. Example of such processing is shown in FIGS. 5h and 5i, in which a structural element on the first device layer 20 is perforated to facilitate removal portions of the insulating layer between the structural element on the first device layer 20 and a large seismic mass 31 on the second device layer 30. A further example of using design for controlling releasing of is suspension structures 32 in the FIGS. 10 and 11. When a lateral dimension of a portion of the insulating material is small, i.e. not more than ten times of thickness of the insulating material layer to be removed by HF vapor etching, such portion of the insulating material is removed in its entirety in the step 607. In the FIGS. 10 and 11, at least one lateral (x and/or y) dimension of the suspension structure 32 is small such that portions of the insulating layer about the poly-Si feedthrough 28 is removed in its entirety so that only the poly-Si feedthrough 28 remains after the HF vapor etching to provide a mechanical coupling and electrical connection between the respective suspension structure 32 and a structural element on the first device layer 20.

In the step 608, structural elements of the first device layer 20 and the second device layer 30 are enclosed in an enclosure by affixing a cap layer 40 on top. The cap layer 40 preferably comprises electrical connections.

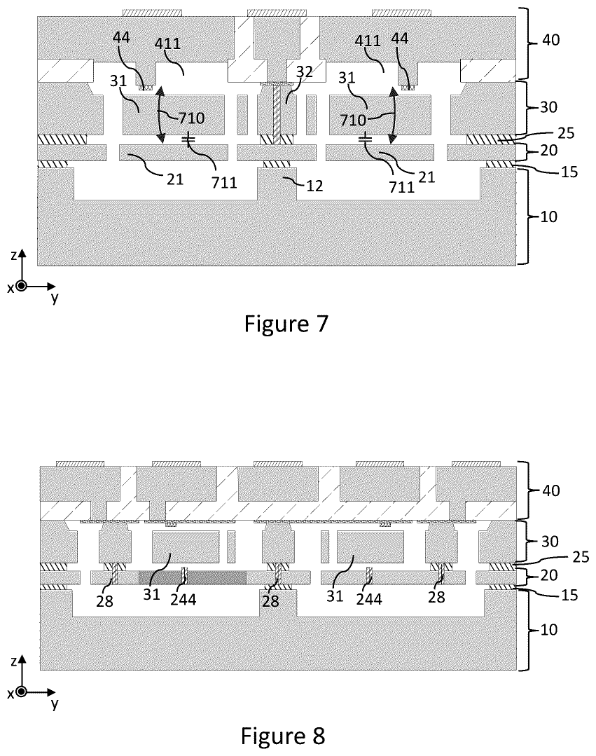

FIG. 7 illustrates a cross-section of a MEMS device according to some exemplary embodiments. In structure according to this embodiment, capacitive electrode pairs may only be formed between the first device layer 20 and the second device layer 30 as illustrated with capacitors 711. This exemplary structure shows two capacitive electrode pairs, each having a static electrode 21 in the first device layer 20 and a seismic mass 31 acting as the moveable electrode on the second device layer 30. Seismic masses 31 are configured to move in the z-axis direction. Capacitance 711 changes in dependence of change of distance between the static electrode 21 and the respective seismic mass 31 acting also as a moveable electrode. In some exemplary embodiments, a separate moveable electrode is attached to a seismic mass 31 such that is moves with the seismic mass in the z-axis direction. At least one cavity 411 is formed in the cap layer 40 to reduce unwanted capacitance between the seismic mass 31 and the cap layer 40. A bumper 44 may be provided in the cap layer 40 for limiting motion of the seismic mass 31 in the z-axis direction for example during testing and/or very harsh conditions, because excess movement of the seismic mass 31 might cause short-circuit of the measurement capacitance or even breaking of the seismic mass 31 itself and/or suspension structures, such as springs or beams thereof. This type of exemplary embodiment with no electrodes on the cap layer 40 enables maximizing stress robustness, since both seismic masses 31 and static electrodes 21 are only attached to the handle wafer 10 and/or to the cap wafer 40 via suspension structures 12, 32. Furthermore, it is preferred that a seismic mass 31 and the respective static electrode 21 are supported at the same lateral location. As understood by the skilled person, the cap layer 40 may comprise both portions with cavity 411 and portions without cavity, possibly with static electrodes 42.

FIG. 8 illustrates a cross-section of a MEMS device according to some exemplary embodiments, with further bumps 244 in the first device layer 20 for limiting movement of one or more inertial masses 31 in the negative z-axis direction. Bumps 244 may be manufactured from poly-Si by adding further steps in the process of manufacturing poly-Si feedthroughs 28.

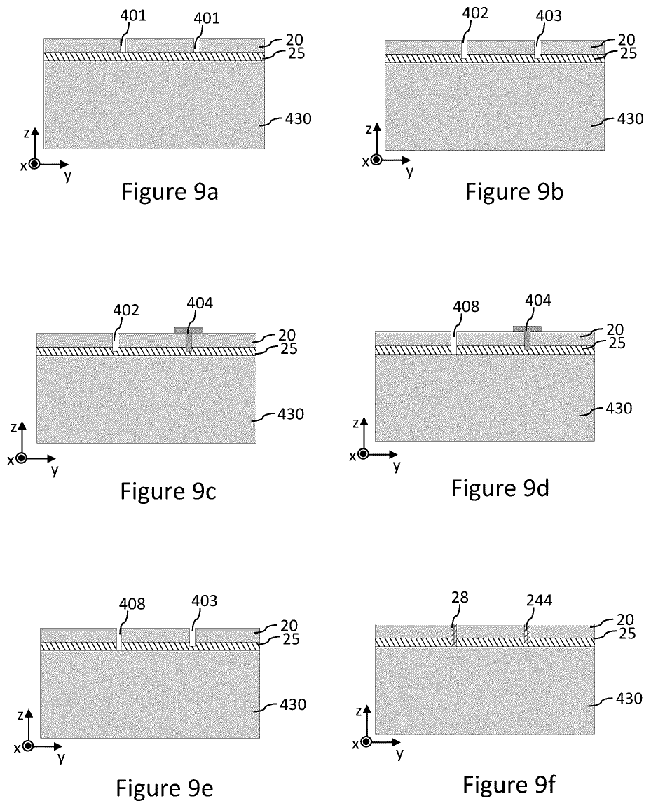

FIGS. 9a to 9f illustrate an exemplary process for manufacturing poly-Si feedthroughs 28 and bumps 244 as shown in the FIG. 8.

In the FIG. 9a, DRIE etching is used for generating holes 401 through the first device layer 20.

As shown in the FIG. 9b, the electrically insulating layer 25 is then etched, but just over a part of the thickness of the electrically insulating layer 25, forming deeper holes 402, 403. Depth of this partial etching of the electrically insulating layer 25 determines how much the poly-Si feedthroughs will protrude above the upper face of the first device layer 20 in the completed structure.

Deeper holes 403, which may be referred to as bump holes, at intended locations of the bumps are then covered by a resist pattern 404 as shown in the FIG. 9c.

As illustrated in the FIG. 9d, etching of the electrically insulating layer 25 is thereafter continued so that feedthrough holes 408 are formed that go all the way through the first device layer 20 and the electrically insulating layer 25, reaching the face of the second device wafer 430.

The resist pattern 404 is then removed as shown in the FIG. 9e, leaving bump holes 403 and feedthrough holes 408 exposed.

Finally, poly-Si is deposited to fill both bump holes 403 and feedthrough holes 408 as illustrated in the FIG. 9f, and upper face of the first device layer 20 is planarized by removing any poly-Si residues not within bump holes 403 and feedthrough holes 408. Upon removal of the electrically insulating layer 25 during the HF release step, bumps 244 are revealed.

FIG. 10 illustrates a cross-section of a variation of the first exemplary embodiment as shown in the FIG. 1. In this variation, the which the suspension structures 32 have a laterally smaller area than in the FIG. 1 such that when the sacrificial electrically insulating layer 25 is removed in the releasing step of the manufacturing process, the insulation material is removed in its entirety between each suspension structure 32, and the respective structural element in first device layer 20. The polysilicon feedthrough 28, here passing through the suspension structure 32 of the second device layer 30, thus forms the mechanical contact between the suspension structure 32 and the respective structural element of the first device layer 20.

FIG. 11 illustrates a cross-section of a variation of the third exemplary embodiment as shown in the FIG. 4l. The suspension structures 32 have a laterally smaller area than in the FIG. 4l such that when the sacrificial electrically insulating layer 25 is removed in the releasing step of the manufacturing process, the insulation material is removed in its entirety between each suspension structure 32, and the respective structural element in the first device layer 20. The polysilicon feedthrough 28, here passing through the structural element of the first device layer 20, thus forming the sole mechanical contact between the suspension structure 32 and the respective structural element of the first device layer 20.

By using the poly-Si feedthrough 28 as the sole mechanical and electrical coupling between a suspension structure 32 and a structural element of the first device layer 20, suspension structures can be made small, which saves lateral area. This is particularly beneficial for implementing double differential comb structures.

FIG. 12 illustrates a cross-section of a further variation of the MEMS device structure according to some exemplary embodiments.

In this variation, a further, electrically conducting, metallic bonding layer 35 is applied between the second device layer 30 and the cap layer 40. The metallic bonding layer 35 is patterned on the cap layer or on the second device layer or both these layers before the MEMS device is enclosed by the cap layer (step 608). The metallic bonding layer may be an AlGe layer, or an Au—Au bonding may be used in which metallic bonding layer is preferably patterned both on the cap layer and the second device layer. As understood by a skilled person, the metallic bonding layer 35 can be applied to any one of the above illustrated exemplary embodiments.

It should be apparent to a person skilled in the art that as technology advanced, the basic idea of the invention can be implemented in various ways. Moreover, it is generally noted that the exemplary embodiments described above are intended to facilitate the understanding of the present invention and are not intended to limit the interpretation of the present invention. The present invention may be modified and/or improved without departing from the spirit and scope thereof, and equivalents thereof are also included in the present invention. That is, exemplary embodiments obtained by those skilled in the art applying design change as appropriate on the embodiments are also included in the scope of the present invention as long as the obtained embodiments have the features of the present invention. For example, each of the elements included in each of the embodiments, and arrangement, materials, conditions, shapes, sizes, and the like thereof are not limited to those exemplified above and may be modified as appropriate. It is to be understood that the exemplary embodiments are merely illustrative, partial substitutions or combinations of the configurations described in the different embodiments are possible to be made, and configurations obtained by such substitutions or combinations are also included in the scope of the present invention as long as they have the features of the present invention.

What is claimed:

1. A microelectromechanical system (MEMS) device comprising:
at least one capacitive electrode pair comprising at least one static electrode and at least one moveable electrode;
a handle layer comprising at least one cavity and at least one suspension structure;
a first device layer comprising the at least one static electrode;
a second device layer comprising at least one seismic element moveably suspended above the first device layer, the at least one seismic element being configured as the at least one moveable electrode or being mechanically coupled to move with the at least one moveable electrode;
a cap layer;
a first electrically insulating layer between the handle layer and the first device layer; and
a second electrically insulating layer between the first device layer and the second device layer,
wherein the at least static electrode is suspended above the cavity by at least one of the at least one suspension structure disposed in the at least one cavity and at least one suspension structure disposed in the second device layer, and
wherein the handle layer, the first device layer, the second device layer, the cap layer, the first electrically insulating layer and the second electrically insulating layer are configured to form an enclosure that accommodates the at least one seismic element, the at least one static electrode and the at least one moveable electrode.

2. The MEMS device according to claim 1, wherein both the first device layer and the second device layer comprise single-crystal silicon.

3. The MEMS device according to claim 1, wherein a thickness of the second device layer is at least twice a thickness of the first device layer.

4. The MEMS device according to claim 1, wherein the first and second electrically insulating layers comprise silicon dioxide.

5. The MEMS device according to claim 1, further comprising at least one polycrystalline silicon feedthrough that extends at least between the first device layer and the second device layer for electrically coupling a structural element of the first device layer to a structural element of the second device layer and/or to an electrical connection in the cap layer.

6. The MEMS device according to claim 5, further comprising at least one poly-Si bump extending from a face of the structural element of the first device layer towards an opposing face of the structural element of the second device layer.

7. The MEMS device according to claim 5, wherein an electrically insulating material in the second electrically insulating layer is removed about the at least one polycrystalline silicon feedthrough such that the at least polycrystalline silicon feedthrough is the only mechanical contact between the respective structural elements of the first device layer and the second device layer.

8. The MEMS device according to claim 1, wherein the first device layer further comprises at least one signal bearing beam configured to provide an electrical connection.

9. The MEMS device according to claim 1, further comprising a metallic bonding layer between the second device layer and the cap layer.

10. A method for manufacturing a MEMS device according to claim 1, the method comprising:
forming the handle layer out of a mono-Si handle wafer, the forming of the handle layer comprising forming at least one cavity and simultaneously forming the at least one suspension structure on a first face of the handle layer, and covering the first face of the handle layer with a first electrically insulating layer;
forming the second electrically insulating layer on a first mono-Si wafer;
fusion bonding a second mono-Si wafer on the second electrically insulating layer;
forming the first device layer out of the second mono-Si wafer, the forming of the first device layer comprising thinning the second mono-Si wafer into a first thickness and forming a plurality of first trenches extending through the first device layer by dry etching, wherein the first device layer comprises the at least one static electrode;
fusion bonding the first device layer on the first electrically insulating layer on the first face of the handle layer;
forming the second device layer out of the second mono-Si wafer, the forming of the second device layer comprising thinning the first mono-Si wafer into a second thickness, forming at least one recessed area in the first mono-Si wafer and dry etching a plurality of second trenches extending through the first mono-Si wafer;
releasing structural elements of the first and second device layer by removing exposed portions of the first and second electrically insulating layers over thickness of the first and second electrically insulating layers by etching; and
enclosing the structural elements within the enclosure by bonding the cap layer on top of the second device layer.

11. The method according to claim 10, further comprising, before the fusion bonding of the second mono-Si wafer on the second electrically insulating layer, pre-etching the second electrically insulating layer for removing at least one portion of the second electrically insulating layer.

12. The method according to claim 11, further comprising forming at least one polycrystalline silicon feedthrough extending between the first device layer and the second device layer for implementing at least one electrical connection between the first device layer and the second device layer.

13. The method according to claim 12,
wherein the at least one poly-Si feedthrough further passes through the first device layer, and
wherein the forming of the at least one polycrystalline silicon feedthrough comprises, after thinning the second device wafer and before dry etching the first device layer, forming at least one feedthrough hole extending through the first device layer and the second insulator layer, depositing polycrystalline silicon for filling the at least one feedthrough hole and removing excess polycrystalline silicon deposited on the face of first device layer by grinding and/or chemical mechanical polishing.

14. The method according to claim 13, further comprising generating at least one motion limiting bump in the first device layer.

15. The method according to claim 12,
wherein the at least one polycrystalline silicon feedthrough further passes through the second device layer, and
wherein the forming of the at least one polycrystalline silicon feedthrough comprises, after thinning the first device wafer and before dry etching the second device layer, forming at least one feedthrough hole extending through the second device layer and the second electrically insulating layer, depositing polycrystalline silicon to fill the at least one feedthrough hole and removing excess polycrystalline silicon deposited on the face of second device layer by grinding and/or chemical mechanical polishing.

16. The method according to claim 12, wherein, during the releasing of the structural elements, a portion of the second insulating layer in vicinity of the at least one polycrystalline silicon feedthrough is removed in its entirety by etching, such that the polycrystalline silicon feedthrough that electrically connects the structural element of the first device layer to the structural element of the second device layer remains as the sole mechanical coupling between the respective structural elements.

17. The method according to claim 10, further comprising perforating at least one structural element of the first device layer for enabling etching to release the at least one seismic element comprised in the second device layer.

18. The method according to claim 10, further comprising forming the cap layer to include at least one bump for limiting movement of the at least one seismic element.

19. The method according to claim 10, further comprising applying a metallic bonding layer between the second device layer and the cap layer.

20. The method according to claim 18, further comprising forming at least one cavity on the face of the cap layer that faces the second device layer.
